(19) United States
(12) Patent Application Publication
(10) Pub. No.: US 2017/0093344 A1
(43) Pub. Date: Mar. 30, 2017

(54) APPARATUS FOR AMPLIFYING HIGH VOLTAGE SIGNALS IN SPACE BASED SYSTEMS

(71) Applicant: U.S.A. as represented by the Administrator of the National Aeronautics and Space Administration, Washington, DC (US)

(72) Inventors: MICHAEL J. MAHON, Severna Park, MD (US); NATHANIEL A. GILL, Ellicott City, MD (US)

(21) Appl. No.: 14/870,455

(22) Filed: Sep. 30, 2015

(51) Int. Cl. H03F 1/30; H03F 3/04

(52) U.S. Cl. CPC H03F 1/30; H03F 3/04; H03F 2200/165; H03F 2200/135

(57) ABSTRACT

An amplifying apparatus appropriate for use in high radiation environments where the amplifier has one or more channels configured to produce one or more output power signals. Each channel has a low pass filter configured to receive an analog signal and produce a filtered analog signal. The low pass filter is configured to attenuate a frequency component of the analog signal having a frequency greater than a predetermined corner frequency. Each channel includes a linear amplifier coupled to the low pass filter and configured to receive the filtered analog signal produced by the low pass filter. The amplifier produces the output power signal that has a high voltage which is a linear multiple of the voltage of the filtered analog signal.

### ORIGIN OF THE INVENTION

The invention described herein was made by employees of the United States Government, and may be manufactured and used by or for the Government for Government purposes without the payment of any royalties thereon or therefore.

### BACKGROUND

Field

The aspects of the present disclosure relate generally to electro-mechanical apparatus and more particularly to signal amplifiers for driving micro-electromechanical devices.

Description of Related Art

Space based missions present particularly harsh environments for operation of electronic equipment. Limited atmosphere complicates removal of heat. Vibration and mechanical stresses can be high, leading to damage of components and packaging. Electronic circuits are also often subjected to high levels of ionizing radiation. For example in some environments electronic equipment needs to withstand and operate correctly when subjected to total ionizing doses reaching a radiation-absorbed-dose (rad) of 100,000 rad or more.

Recently, micro-electromechanical systems (MEMS) are becoming available for a variety of uses. MEMS devices are generally miniature electromechanical devices constructed using techniques of microfabrication and are sometimes referred to as microsystems technology or micro-machined devices. These MEMS devices can have a critical physical dimension ranging from below one micron to several millimeters. One class of MEMS devices includes micro-actuators for use in optical devices and are sometimes referred to as micro optical electromechanical devices (MOEMS). MOEMS may be used to create optical switches and mirrors to redirect or modulate light beams, or as independently controlled micro-mirror arrays for displays. Many MEMS mirror devices require high actuator voltages, often exceeding one hundred volts, and present as capacitive or purely capacitive loads resulting in the need for specialized drive circuitry.

Accordingly, it would be desirable to provide a high voltage amplifier that addresses at least some of the problems identified above.

### BRIEF DESCRIPTION OF THE DISCLOSED EMBODIMENTS

As described herein, the exemplary embodiments overcome one or more of the above or other disadvantages known in the art.

One aspect of the disclosed embodiments relates to an amplifying apparatus appropriate for use in high radiation environments where the amplifier has one or more channels. Each channel has a low pass filter configured to receive an analog signal and produce a filtered analog signal. The low pass filter is configured to attenuate a frequency component of the analog signal having a frequency greater than a predetermined corner frequency. Each channel includes a linear amplifier coupled to the low pass filter and is configured to receive the filtered analog signal produced by the low pass filter. The amplifier produces the output power signal that has a voltage which is a linear multiple of the voltage of the filtered analog signal.

A second aspect of the disclosed embodiments relates to an apparatus that includes an amplifying device and a micro-electromechanical mirror. The amplifying device has four amplifying channels, and the micro-electromechanical mirror has a first axis of motion and a second axis of motion. A first amplifying channel and a second amplifying channel are coupled to the first axis and configured to differentially operate the first axis. A third amplifying channel and a fourth amplifying channel are coupled to the second axis and are configured to differentially operate the second axis.

These and other aspects and advantages of the exemplary embodiments will become apparent from the following detailed description considered in conjunction with the accompanying drawings. It is to be understood, however, that the description and drawings are designed solely for purposes of illustration and not as a definition of the limits of the invention, for which reference should be made to the appended claims. Additional aspects and advantages of the invention will be set forth in the description that follows, and in part will be obvious from the description, or may be learned by practice of the invention. Moreover, the aspects and advantages of the invention may be realized and obtained by means of the instrumentalities and combinations particularly pointed out in the appended claims.

### BRIEF DESCRIPTION OF THE DRAWINGS

In the drawings:

FIG. 1 illustrates a block diagram of a space qualified apparatus incorporating aspect of the disclosed embodiments for producing one or more power signals.

FIG. 2 illustrates a schematic diagram of an exemplary low voltage differential signal receiver circuit incorporating aspects of the disclosed embodiments.

FIG. 3 illustrates an exemplary signal distribution circuit incorporating aspects of the disclosed embodiments appropriate for distributing single ended digital signals.

FIG. 4 illustrates a diagram of an exemplary digital to analog conversion circuit incorporating aspects of the disclosed embodiments.

FIG. 5 illustrates a schematic diagram of an exemplary low pass filter circuit incorporating aspects of the disclosed embodiments.

FIG. 6 illustrates a schematic diagram of an exemplary high voltage amplifier incorporating aspects of the disclosed embodiments.

FIG. 7 illustrates a schematic diagram of an exemplary flyback type switching regulator incorporating aspects of the disclosed embodiments.

FIG. 8 illustrates a schematic diagram of an exemplary power conditioning circuit incorporating aspects of the disclosed embodiments.

### DETAILED DESCRIPTION OF THE DISCLOSED EMBODIMENTS

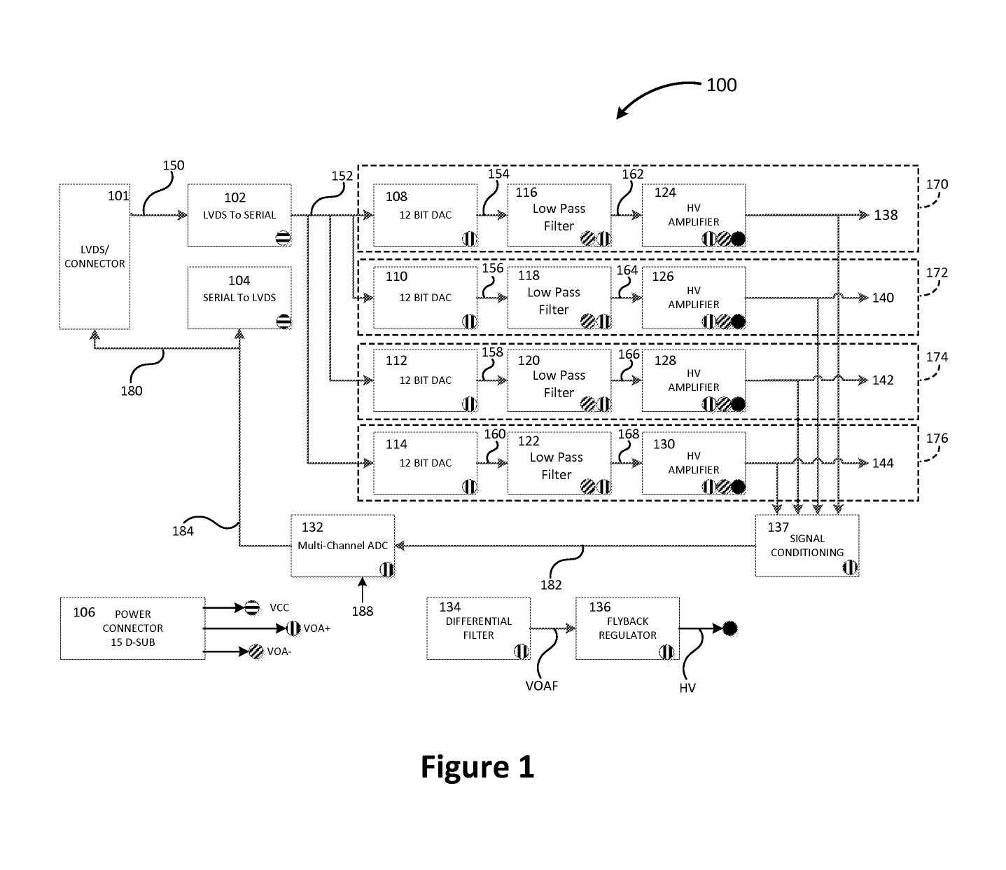

FIG. 1 illustrates a block diagram of a space qualified amplifying apparatus 100 for producing one or more power signals. The exemplary amplifying apparatus 100 is configured to produce four power signals 138, 140, 142, 144 appropriate for driving micro-electromechanical system (MEMS) devices having two axes of movement. Alternatively the amplifying apparatus 100 may be configured to produce more or less than four power signals 138, 140, 142, 144 and may be advantageously employed to drive a variety of load types requiring a high voltage amplified power signal. Each power signal 138, 140, 142, 144 comprises a high voltage, such as for example about 130 to about 140 volts or other desired high voltage, and is configured to drive a capacitive load consistent with the load which may be presented by MEMS devices such as a multi axis MEMS mirror module. The power signals 138, 140, 142, 144 are proportional to serial digital data received as low voltage differential signals (LVDS) 150 through an electrical connector 101.

The exemplary amplifying apparatus 100 may be constructed on a single circuit card configured to receive power through a power connector 106. Alternatively the amplifying apparatus 100 may be constructed on more than one circuit card with appropriate power being distributed to each card. Power connector 106 may be a 15 pin D type connector or other suitable connector appropriate for coupling the amplifying apparatus 100 to external power sources. Three different supply voltages or power sources VCC, VOA+, VOA− are received through the power connector 106. The connector 106 provides a low voltage for digital circuitry VCC, a positive analog supply voltage VOA+ and a corresponding negative analog supply voltage VOA−. The positive analog supply voltage VOA+ and the negative analog supply voltage VOA− are used to provide power to operational amplifiers and other low voltage analog circuitry.

Power distribution within the amplifying apparatus 100 is indicated with patterned circles. Each power source VCC, VOA+, VOA− brought in through the power connector 106 is marked with a patterned circle and each module in the apparatus 100 is decorated with corresponding patterned circles indicating the power source received by the module. Power distribution for the positive analog supply voltage VOA+ is indicated by circles patterned with vertical lines, power distribution for the negative analog supply voltage VOA− is indicated by circles patterned with diagonal lines, power distribution for the low level digital logic voltage VCC is indicated by patterned circles with horizontal lines, and distribution of the high voltage HV generated by the flyback converter 136 is indicated by solid circles.

A differential filter 134 receives the positive analog supply voltage VOA+ from the power connector 106 and produces a filtered positive voltage VOAF. The differential filter 134 provides a clean or noise free power source for a power converter 136 and also prevents any noise from the power converter 136 from leaking back onto the positive analog supply voltage VOA+. The filtered analog supply voltage VOAF is coupled to a high voltage power converter 136 configured to produce a high positive voltage HV such as a positive voltage at about one hundred and thirty volts (130V) to one hundred and forty volts (140V). The high voltage power converter 136 may be any type of power converter capable of producing an appropriately high voltage.

In the exemplary embodiment shown in FIG. 1 a flyback voltage converter 136 operating in discontinuous conduction mode (DCM) is illustrated. DCM is preferable because it affords a simpler control loop design and has lower turn-on losses. Alternatively the flyback voltage converter 136 may be configured to operate in continuous conduction mode (CCM). Other types of power converters configured to produce an appropriately high voltage HV from the filtered analog supply voltage VOAF may also be advantageously employed in the amplifying apparatus 100.

A MEMS mirror be configured with two orthogonal axes of motion adapted to be driven using a Cartesian coordinate system. A Cartesian coordinate system is a two dimensional coordinate system having two perpendicular or orthogonal axes defining a two dimensional plane. A MEMS mirror based on Cartesian coordinates may be driven by four power signals, such as power signals 138, 140, 142, 144 as illustrated in the exemplary amplifying apparatus 100. Separate power signals are generated to drive the mirror in a positive and a negative direction for each axis of motion, referred to as the X axis and the Y axis, resulting in four control signals: a negative Y axis power signal 138, a negative X axis power signal 140, a positive X axis power signal 142, and a positive Y axis power signal 144. Configuring the power signals 138, 140, 142, 144 in this fashion allows use of a single high voltage power converter 136 producing a single positive high voltage HV for powering the high voltage amplifiers 124, 126, 128, 130 thereby eliminating the need for a negative high voltage power supply or double ended amplifiers.

Each of the power signals 138, 140, 142, 144 is generated by a separate amplifying channel where the negative Y axis power signal is generated by a first channel 170, the negative X axis power signal 140 is generated by a second channel 172, the positive X axis power signal 142 is generated by a third channel 174, and the positive Y axis power signal is generated by a fourth channel 176. Each of the parallel amplifying channels 170, 172, 174, 176 includes the same component modules: a digital to analog converter (DAC) 108, 110, 112, 114, a low pass filter 116, 118, 120, 122, and a high voltage amplifier 124, 126, 128, 130.

Control inputs are brought into the exemplary amplifying apparatus 100 through a digital connector 101 where each signal is received as a low voltage differential signal (LVDS), also referred to herein as a differential signal. A differential signal is a signal carried on two lines where the signal information may be determined by a receiver that monitors voltage differences between the two lines. Each differential signal may be carried over a twisted pair of wires and if desired the twisted pair may include outer shielding to reduce the amount of noise or interference introduced onto the signal by the environment. The LVDS data 150 includes four serial digital signals, one for each channel 170, 172, 174, 176 along with clock, synchronization, and control signals. A LVDS to serial digital data conversion circuit 102 is used to create single ended digital control signals 152 for each of the four amplifying channels 170, 172, 174, 176.

The conversion circuit 102 is powered from the positive low voltage VCC power signal distributed from the power connector 106. The clock, synchronization, and control signals included in the LVDS digital data 150 are used to support operation of analog to digital and digital to analog conversion circuitry. Each DAC circuit 108, 110, 112, 114, is powered by an intermediate voltage derived from the positive analog supply voltage VOA+, and is configured to produce an analog control signal 154, 156, 158, 160. The analog control signals 154, 156, 158, 160 are relatively low voltage having a voltage range such as about zero to five volts. The voltage of each analog control signal 154, 156, 158, 160 is determined by a binary value of the serial digital data 152 corresponding to each parallel channel 170, 172, 174, and 176.

MEMS such as a MEMS mirror devices, often have low resonant frequencies that should be avoided to prevent damaging the devices during operation. This is especially true in missions where maintenance is difficult or may not be possible at all. In the exemplary amplifying apparatus 100, potentially harmful frequencies are removed from, or filtered out of, the analog control signals 154, 156, 158, 160, by four low pass filters 116, 118, 120, 122, to produce four filtered control signals 162, 164, 166, 168 respectively. Each of the low pass filters 116, 118, 120, 122, may be implemented as a sixth order Bessel filter or other appropriate low pass filter with a corner frequency of about 475 Hertz (Hz), selected based on the particular MEMS device being driven by the power signals 138, 140, 142, 144. The low pass filter is configured to produce a filtered analog control signal where frequency components of the filtered control signal above the corner frequency are attenuated with respect to the input control signal and frequency components below the corner frequency are passed without attenuation.

The filtered control signals 162, 164, 166, 168, are amplified by a high voltage amplifier 124, 126, 128, 130 configured to produce the output power signals 138, 140, 142, 144 respectively. The high voltage amplifiers 124, 126, 128, 130 have a gain, such as for example about 28 times, which when applied to the filtered control signals 162, 164, 166, 168 will raise the voltage of the filtered control signals 162, 164, 166, 168 to a high voltage level appropriate for the particular device being driven. In certain embodiments, such as when driving MEMS mirror devices, the load being driven may be capacitive in nature with a capacitance in the range of about 20 pico-Farads (pF). In these embodiments the power signals 138, 140, 142, 144 may be configured to have a low wattage such as around one milliwatt (mW) with a relatively high voltage, such as about 130 to 140 volts.

The exemplary amplifying apparatus 100 may be configured to provide feedback signals 180 derived from the power signals 138, 140, 142, 144. This allows a controller or other processing apparatus (not shown) to use closed loop control techniques to control the power signals 138, 140, 142, 144. The power signals 138, 140, 142, 144 are received by signal conditioning circuits 137 that sense the voltage of each power signal 138, 140, 142, 144, and produce power sensing signals 182. The power sensing signals 182 are converted to serial digital signals 184 by multi-channel analog to digital converter 132. In certain embodiments it is desirable to obtain temperature information pertaining to the amplifying apparatus 100 or other devices (not shown) that may be consuming the power signals 138, 140, 142, 144. In embodiments where temperature information is desired, the ADC 132 may be used to convert analog temperature sensor signals 188 to digital data signals 184. A serial to LVDS converter circuit 104 is used to convert the serial digital signals 184 to LVDS signals which are coupled to the digital connector 101 where they may be coupled to a controller or other processing apparatus (not shown).

Each high voltage amplifier 124, 126, 128, 130 scales a low voltage filtered control signal 162, 164, 166, 168, such as an about zero to positive five volt filtered control signal, to a high voltage signal, such as about zero to one hundred and forty volts. The high voltage amplifier 124, 126, 128, 130 has a relatively high full power bandwidth, such as greater than about 50 kilohertz (KHz). The full power bandwidth is the frequency below which the amplifier gain or scale factor remains constant and the amplifier imparts little or no phase delay on the input signal. In certain embodiments the low pass filter 116, 118, 120, 122 is implemented as a Bessel filter. A Bessel filter has the advantageous property of imparting a constant group delay on signals below the corner frequency of the filter, such as about 475 Hz, or more generally below about 1000 Hz. It is important that the high voltage amplifier 124, 126, 128, 130 exhibits a flat frequency and phase response well past the corner frequency of the low pass Bessel filter to ensure both linearity of the drive channel 170, 172, 174, 176 and to preserve the constant group delay of the low pass filter 116, 118, 120, 122 over the frequency range of interest. The frequency range of interest is the range of frequencies for which the system as a whole, i.e. the system including the amplifying apparatus 100 and a load, such as a MEMS mirror device (not shown), are desired to operate. Maintaining a constant group delay through the amplifying apparatus 100 allows for constant time delay correction of the digital drive signal 150 with respect to position in time of a MEMS mirror (not shown) being driven by the four power signals 138, 140, 142, 144 produced by the amplifying apparatus 100.

The amplifying apparatus 100 includes four independent drive channels 170, 172, 174, 176 that may be used to drive a MEMS mirror device having two orthogonal directions of motions. Each of the two orthogonal directions of motion correspond to an axis in a Cartesian coordinate system. By using two drive channels 170, 176 to drive the first axis of motion and the other two drive channels 172, 174 to drive the second axis of motion, each axis of the MEMS mirror device may be operated differentially. Differential operation of an axis of motion refers to using separate drive signals to achieve motion in each of the positive and negative directions along the axis of motion enabling symmetric actuation forces to be applied about any desired position or set point. This differential operation of the axes significantly improves the linearity of the mirror motion with respect to the control inputs 150. Because the digital control inputs 150 can drive each channel separately, many types of complex and advantageous digital control algorithms may be employed to generate the digital control inputs 150 and control positioning of the MEMS mirror.

In certain embodiments it is desirable to construct the entire amplifying assembly, such as amplifying assembly 100, on a single circuit card. When constructing such an amplifying assembly on a single printed circuit board, care must be taken to prevent interaction of the fast switching digital signals 150, 152 and the slow moving analog control signals 154, 156, 158, 160. Fast switching digital currents often develop AC voltages across the power return or ground plane of a printed circuit card that can interact with and induce undesirable electrical noise on the more slowly moving analog signals. A critical area of a printed circuit card is in the neighborhood of the DAC circuitry 108, 110, 112, 114 where the fast moving digital signals and slower moving analog signals are in close proximity. Typically interaction is controlled by connecting separate analog and digital return paths near each DAC. However, when multiple DAC 108, 110, 112, 114 and ADC 132 modules are included on a single printed circuit card it is not possible to separate the digital and analog return connections of each module. In the exemplary amplifying apparatus 100 electrical noise may be controlled by keeping the digital and analog circuitry spatially separated by placing the digital circuitry 102, 104, 108, 110, 112, 114 on one side of the printed circuit board and the analog circuitry 116, 118, 120, 122, 124, 126, 128, 130 on an opposite side of the printed circuit board. Modules that include both digital and analog circuitry, such as the DAC 108, 110, 112, 114 and ADC 132 modules are centrally located between the digital and analog circuitry. Spatially separating the digital and analog circuitry prevents signal overlap thereby minimizing signal coupling as well as return current induced voltages.

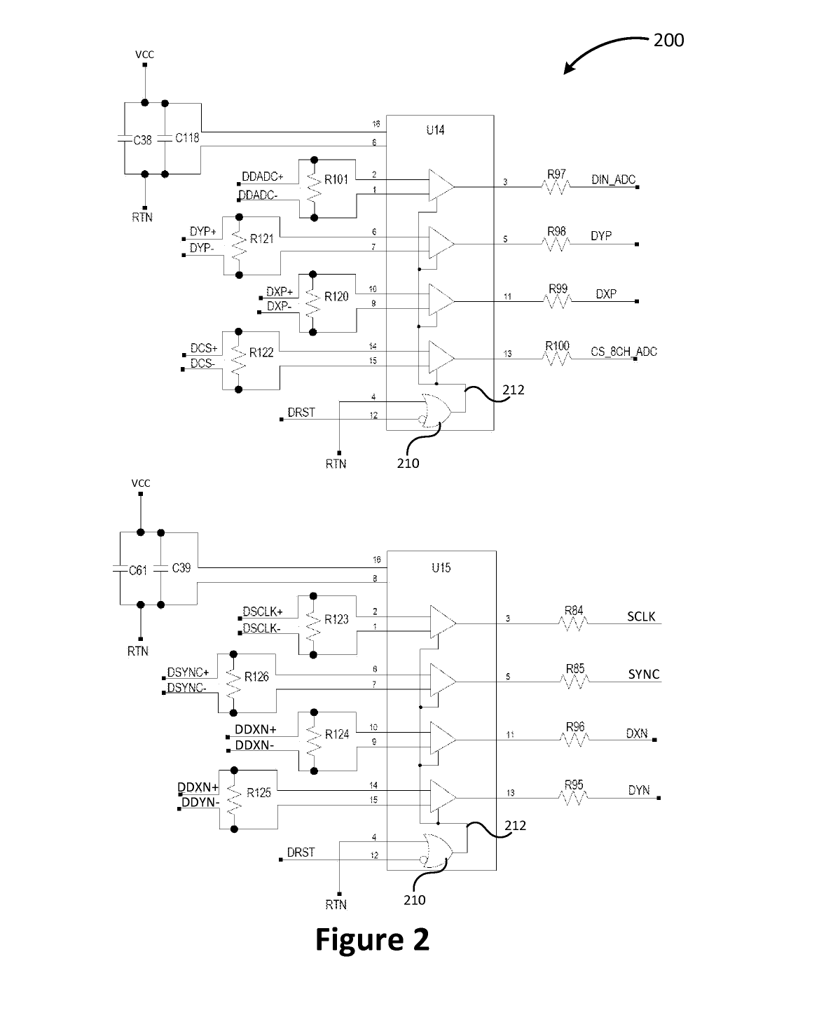

FIG. 2 illustrates a schematic diagram of an exemplary LVDS receiver circuit 200 configured to receive LVDS data, such as the LVDS data signals 150, and convert the received LVDS data into single ended digital signals, such as the digital data 152 described above. The two integrated circuits (IC) U14, U15 are configured to receive eight differential digital data signals These ICs U14, U15 receive their operating power from a low voltage power source VCC, such as for example a +3.3V power source. The first IC U14 receives VCC power on pin 16 and the associated power return RTN is connected to pin 8. A pair of decoupling capacitors C38, C118 are connected in parallel between the power source VCC and the return or common. The capacitors C38 and C118 are physically located close to the IC U14 to improve decoupling performance. Similarly the IC U15 receives its low voltage power VCC on pin 16 and has the associated power return signal RTN connected to pin 8 with a pair of decoupling capacitors C61, C39 connected in parallel between pin 16 and pin 8 located close to the IC U15. The exemplary circuit 200 is appropriate for use as an LVDS to serial digital data conversion circuit 102 as may be included in the amplifying apparatus 100.

LVDS type signals are received over a pair of lines: a positive signal line indicated by a trailing plus ‘+’ sign following the signal designation, and a return or negative signal line indicated by a trailing minus sign ‘−’ following the signal designation. For example the positive differential clock signal is denoted as DSCLK+, and the return or negative differential clock signal is denoted as DSCLK−. Differential digital data for control of an ADC, DDADC+, DDADC−, is received onto pins 1 and 2 of IC U14. A terminating resistor R101 is connected across the differential signal DDADC+, DDADC− and located near the IC U14. The differential data for the ADC signal, DDADC, is converted to digital input data for an ADC DIN_ADC at pin 3 of IC U14 and made available to other circuits through a series resistor R97.

A differential signal representing control information for the positive Y axis channel DYP+, DYP− is received from an external source onto pins 6 and 7 of IC U14. A terminating resistor R121 is connected across the differential signal DYP+, DYP- and located near the IC U14. The differential positive Y axis data DYP is converted to serial digital control signal for the positive Y axis at pin 5 of IC U14 and made available to other circuits through a series connected resistor R98. A differential signal with control information for the positive X axis DXP+, DXP− is received from an external source onto pins 9 and 10 of the IC U14 with a terminating resistor R120 connected across pins 9 and 10 of the IC U14. The differential signal DXP+DXP− is converted to a serial digital control signal for the positive X axis at pin 11 of IC U14 and is made available to other circuits through a series connected resistor R99.

A differential control signal DCS+, DCS− is received from an external source onto pins 14 and 15 of the IC U14 with a terminating resistor connected across pins 14 and 15 of IC U14. The differential control signal DCS+, DCS− is converted to a digital chip select signal for an eight channel ADC CS_8CH_ADC and made available an ADC circuit through a series connected resistor R100. The chip select signal CS_8CH_ADC the data-in signal for the ADC DIN_ADC may be used as control signals for an ADC. Such as an ADC may be configured to provide digital feedback information. A differential serial clock signal DSCLK+, DSCLK− is received from an external source onto pins 1 and 2 of IC U15 with a terminating resistor R123 connected across pins 1 and 2 of IC U15. The differential serial clock signal DSCLK+, DSCLK− is converted to a single ended serial clock SCLK on pin 3 of the IC U15 and made available to other circuits through a series connected resistor R84.

A differential synchronization signal DSYNC+, DSYNC− is received from an external source onto pins 6 and 7 of the IC U15 with a terminating resistor R126 connected across pins 6 and 7 of the IC U15. The differential synchronization signal DSYNC+, DSYNCH− is converted to a single ended synchronization signal SYNC at pin 5 of the IC U15 and made available to other circuits through a series connected resistor R85.

A differential signal with control information for the negative X axis DXN+, DXN− is received from an external source onto pins 9 and 10 of the IC U15 with a terminating resistor R124 connected across pins 9 and 10 of the IC U15. The differential control information for the negative X axis DXN+, DXN− is converted to a serial digital control signal for the negative X axis DXN on pin 11 of the IC U15 and made available to other circuits through a series connected resistor R96.

A differential signal with control information for the negative Y axis DYN+, DYN− is received from an external source onto pins 14 and 15 of the IC U15 with a terminating resistor R125 connected across pins 14 and 15 of the IC U15. The differential control information for the negative Y axis DYN+, DYN− is converted to a serial digital control signal for the negative Y axis DYN on pin 13 of the IC U15 and made available to other circuits through a series connected resistor R95.

The differential receiver ICs U14 and U15 include internal logic 210 for generating a reset signal that holds the output pins 3, 5, 11, and 13 of each IC U14, U15 low during a circuit reset period. The reset signal 212 is controlled by a digital reset signal DRST connected to pin 12 of IC U14 and pin 12 of IC U15 with pin 4 of IC U14 and pin 4 of IC U15 connected to the return RTN of the low voltage power.

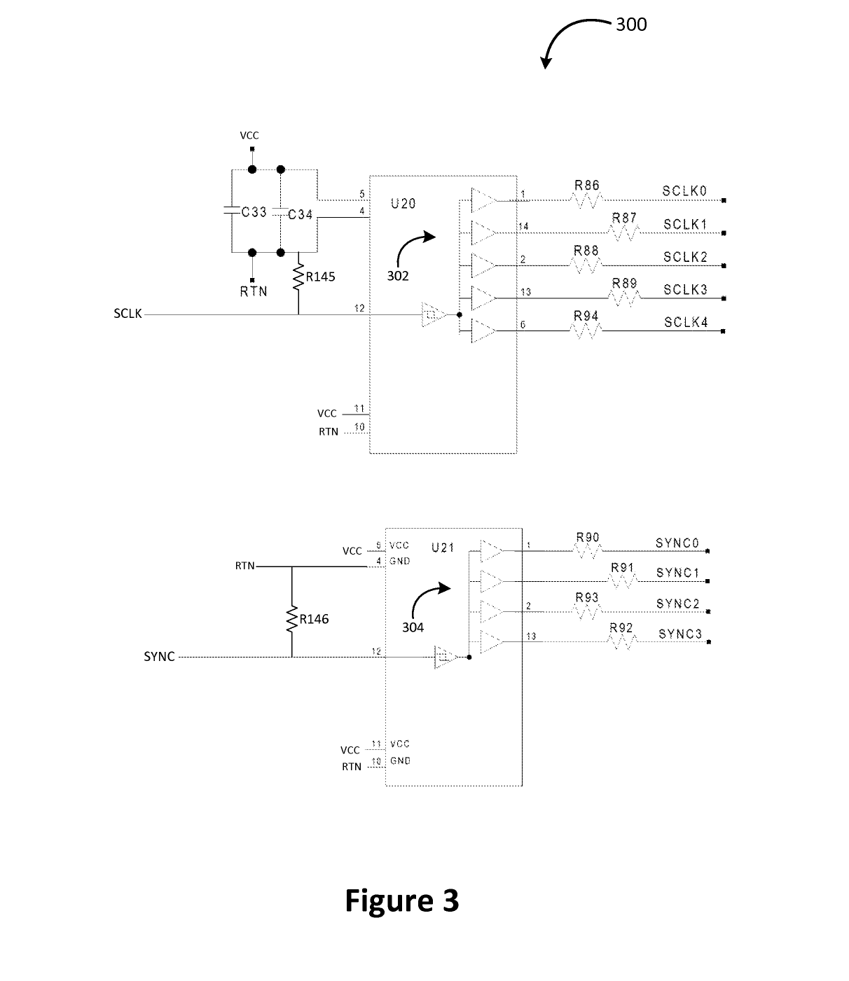

FIG. 3 illustrates an exemplary signal distribution circuit 300 appropriate for distributing single ended digital signals. The exemplary signal distribution circuit 300 includes two buffer ICs U20, U21 powered from the low voltage power VCC connected to pins 5 and 11 of each IC U20 and U21 with the associated power return RTN connected to pins 4 and 10 of each IC U20 and U21. In certain embodiments it may be desirable to use decoupling capacitors to reduce noise on the power pins 5 and 10 of each IC U20, U21. An exemplary arrangement of decoupling capacitors is illustrated by the decoupling capacitors C33 and C34 connected across pins 4 and 5 of IC U20. For best performance the decoupling capacitors C33 and C34 should be located close to the power pins 4 and 5 of IC U20. IC U20 receives the serial clock signal SCLK from the receiver circuit 200 on pin 12 with a pull down resistor R145 connected between the serial clock signal SCLK and the power return RTN. The IC U20 includes internal drivers 302 that replicate the SCLK signal onto pins 1, 14, 2, 13 of IC U20.

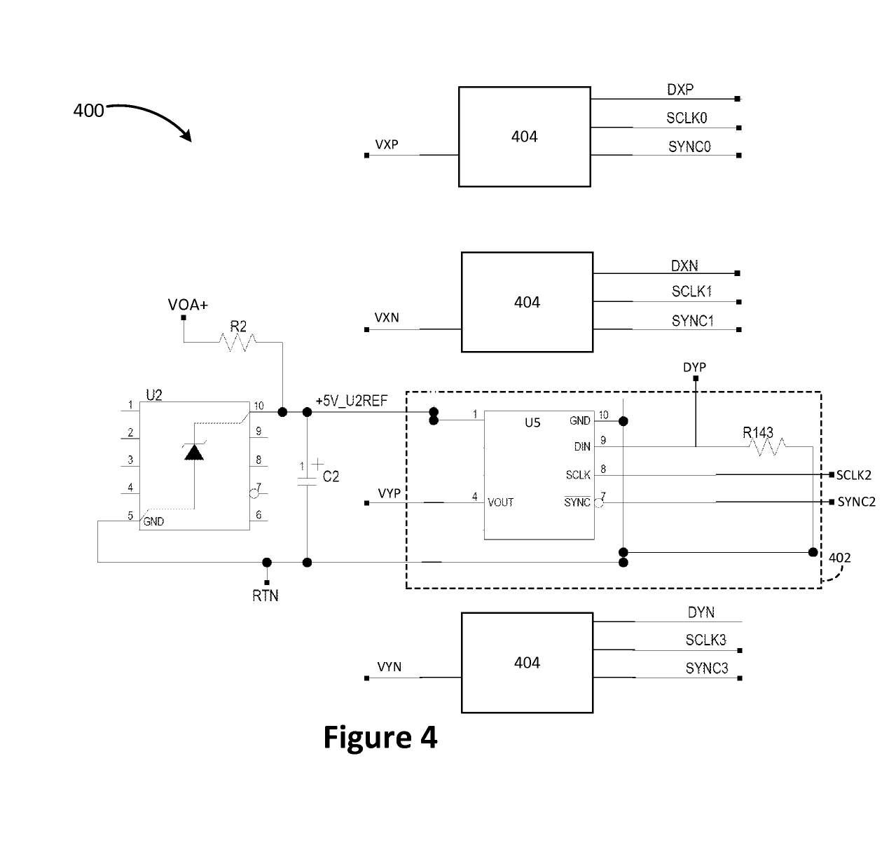

The first four replicated serial clock signals SCLK0, SCLK1, SCLK2, SCLK3, are provided through series connected resistors R86, R87, R88, R89 respectively, for use by DAC circuits described in further detail below. A fifth serial clock signal SCLK4 is provides through a series connected resistor R94 to an ADC circuit, such as the multi-channel ADC 132 in amplifying apparatus 100. The IC U21 includes internal drivers 304 that replicate the synchronization signal SYNC produced by the exemplary receiver circuit 200 to produce four synchronization signals on pins 1, 14, 2, and 13 of IC U21. The synchronization signal SYNC is received on pin 12 of IC U21 with a pull down resistor between the synchronization signal SYNC and the power return RTN. The four replicated synchronization signals SYNC0, SYNC1, SYNC2, SYNC3 are provided through series connected resistors R90, R91, R93, R92 to DAC circuits such as the exemplary DAC circuit 400 described below with reference to FIG. 4.

FIG. 4 illustrates a diagram of an exemplary digital to analog conversion (DAC) circuit 400 appropriate for converting single ended serial digital data, such as the single ended serial digital data 152, to analog control signals, such as the analog control signals 154, 156, 158, 160. The exemplary digital to analog conversion circuit 400 includes four DAC circuits 402, 404, 406, 408 appropriate for use as the four DAC modules 108, 110, 112, 114 described above with reference to amplifying apparatus 100. A single converter power rail +V_U2REF provides operating power to all four DAC circuits 402, 404, 406, 408. The positive supply voltage VOA+, which in certain embodiments may have a voltage of about positive 12 volts, provides power through a series connected resistor R2 to a converter power rail +V_U2REF. The power rail +V_U2REF may have a positive voltage such as about five volts. A Zener diode D1 is connected between the converter power rail +V_U2REF and a power return or common RTN and maintains the converter power rail +V_U2REF at a constant desired voltage. Filtering of the converter power rail +V_U2REF may be provided by a capacitor C2 connected between the converter power rail +V_U2REF and the power return RTN.

An exemplary digital to analog converter circuit 402 includes a DAC IC U5 coupled to the converter power rail +V_U2REF and power return RTN. The DAC IC U5 receives a serial clock signal SCLK0 and a synchronization signal SYNC0. The synchronization signal SYNC0 may be generated by a signal distribution circuit such as the signal distribution circuit 300. The serial clock signal SCLK0 and synchronization signal SYNC0 are used to convert serial digital control information DYP into a binary value within the DAC IC U5 and produce a corresponding analog control voltage VYP. When more than one amplifier channel is desired, such as the four amplifying channels 170, 172, 174, 176 of the amplifying apparatus 100, additional DAC circuits 404, 406, 408 may be included.

The exemplary DAC circuit 400 illustrates an embodiment which includes four DAC circuits 402, 404, 406, 408 to support a four channel amplifying apparatus such as amplifying apparatus 100. The additional DAC circuits 404, 406, 408 receive serial clock signals SCLK1, SCLK2, SCLK3 and synchronization signals SYNC1, SYNC2, SYNC3 from a signal distribution circuit, such as the signal distribution circuit 300. Serial digital control signals DXP, DXN, DYN are provided to the additional DAC circuits 404, 406, 408 to produce analog control signals VXP, VXN, VYN respectively. The additional DAC circuits 404, 406, 408 may also be powered from the converter supply rail +V_U2REF or alternatively may have separate operating power sources.

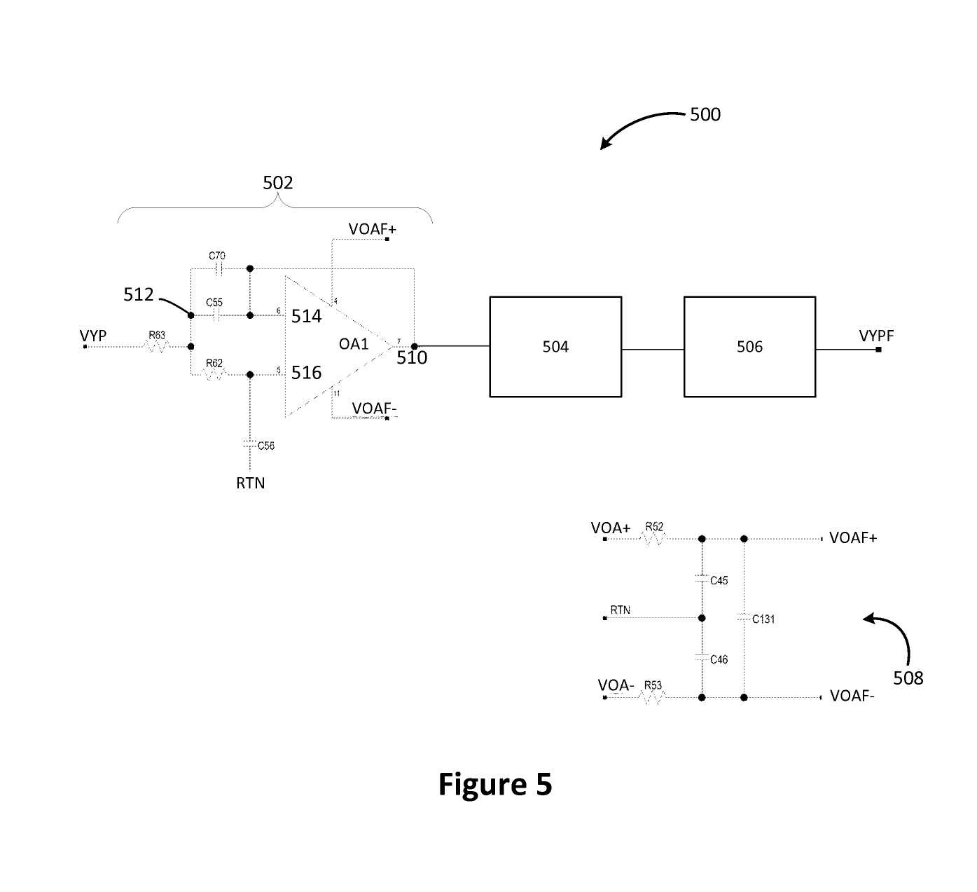

FIG. 5 illustrates a schematic diagram of an exemplary low pass filter circuit 500 appropriate for filtering an analog control signal such as the analog control signals VYP, VXP, VXN, VYN produced by the DAC circuit 400. The low pass filter 500 includes three stages 502, 504, 506, where each stage is made up of a second-order active filter based on the Sallen-Key filter topology. In the exemplary low pass filter 500 all three stages 502, 504, 506 use the same Sallen-Key topology. In certain embodiments it is desirable to have all three stages 502, 504, 506 use the same low pass filter topology. Alternatively the three filter stages 502, 504, 506 may be constructed with different types of filtering circuits.

To improve operation in harsh environments, such as environments encountered during space based missions, the analog supply voltages VOA+ and VOA− are conditioned with a filter 508 physically located close to the low pass filter 500. The filter 508 includes a capacitor C52 connected between the positive analog supply voltage VOA+ and the power return RTN, a capacitor C53 connected between the negative analog supply voltage VOA− and the power return RTN, and a capacitor connected between the positive analog supply voltage VOA+ and the negative analog supply voltage VOA−. The filter 508 is configured to stabilize the filtered analog supply voltages VOAF+, VOAF−, which are then provided to the operational amplifier (op-amp) OA1. In certain embodiments it is advantageous to provide the filtered analog supply voltages VOA+, VOA− to the other filter stages 504 506. The filter 500 is appropriate for use as a low pass filter 116, 118, 129, 122 in any of the channels 170, 172, 174, 176, of the amplifying apparatus 100 described above. When each of the second 504 and third 506 stages are constructed using the exemplary Sallen-Key low pass filter circuit illustrated in the first stage 502, the filter 500 results in a filter characteristic of a sixth order Bessel filter with a predetermined corner frequency, such as about 475 Hz or more generally less than about 1000 Hz.

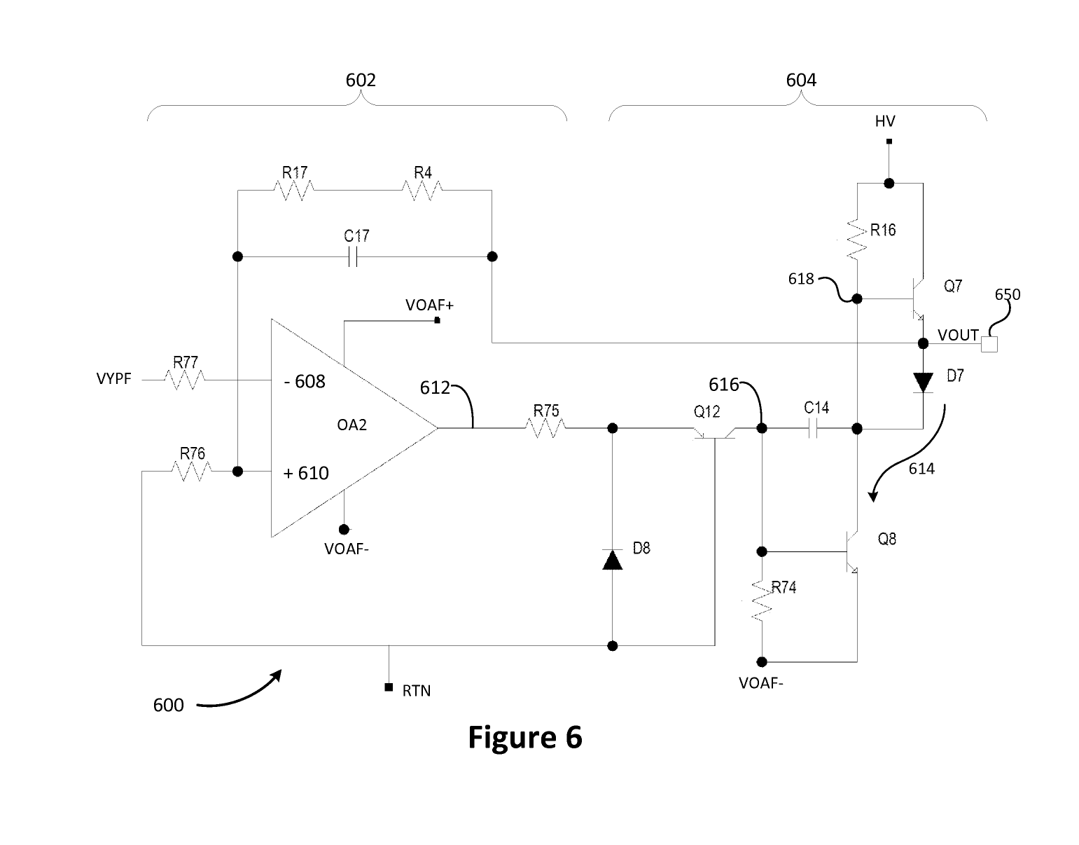

Referring now to FIG. 6 there can be seen a schematic diagram of an exemplary high voltage amplifier 600. The high voltage amplifier 600 incorporates a modified emitter follower type power amplifier 604 and a control circuit 602 to produce a high voltage output power signal VOUT having a voltage proportional to a filtered analog control voltage VYPF. The high voltage amplifier 600 may be advantageously employed in the amplifying apparatus 100 as any of the high voltage amplifiers 124, 126, 128, 130 in the four amplifying channels 170, 172, 174, 176.

An op-amp OA2 compares a filtered analog control voltage VYPF, received by the op-amp OA2 on the inverting input 608 through a series connected resistor R77, with a feedback signal received by the op-amp OA2 on the non-inverting input 610. The feedback signal is derived from the high voltage output power signal VOUT with a resistor divider network formed by three series connected resistors R4, R17, and R76 where the first two series connected resistors R17 and R18 form an upper leg and a single resistor R76 forms a lower leg of the resistor divider.

The op-amp OA2 produces an amplifier input signal 612 used to drive the power amplifier 604. The control circuit 602 monitors the output power signal VOUT and adjusts an amplifier input signal 612 such that the output power signal VOUT is maintained at a linear multiple of the filtered analog control voltage VYPF.

A PNP type bipolar junction transistor (BJT) Q7 operates as the output transistor of the power amplifier 604 and provides power from a high voltage power source HV to the high voltage output power signal VOUT connected to the emitter of the output transistor Q7. The high voltage power source HV has a relatively high positive voltage such as about one hundred and thirty (130) to one hundred and forty volts (140V) of output power. A load 650 may be connected between the output power signal 650 and the power return RTN. The amount of power, or voltage, delivered to a load 650 by the output power signal VOUT is proportional to a drive signal 618 applied to the base of the output transistor Q7. The collector of the output transistor Q7 is connected to the high voltage power source HV and the emitter of the output transistor Q7 is connected to the high voltage output power signal VOUT. A biasing resistor R16 is connected between the base of the output transistor Q7 and the high voltage power source HV to provide biasing current to the base of the output transistor Q7. In certain embodiments the load 650 may be capacitive requiring power to be applied and removed by the output power signal VOUT. A MEMS mirror device is one example of an appropriate type of load 650 to be driven by the high voltage output power signal VOUT.

The power amplifier 604 receives the amplifier input signal 612 through a series connected resistor R75 onto the emitter of a PNP type BJT Q12. The emitter of BJT Q12 is prevented from being pulled to a negative voltage by a diode D8 connected between the emitter of the BJT Q12 and the power return RTN, also referred to herein as common, or ground, with the cathode of the diode D8 connected to the emitter of the BJT Q12. The collector of BJT Q12 provides current to the base of a PNP type BJT Q8 connected between the drive signal 618 and a negative filtered analog voltage VOAF−, such as the about negative twelve volt filtered negative analog supply voltage VOAF− produced by the filter 500 described above.

The collector of the BJT Q8 is connected to the drive signal 618 and the emitter of the BJT Q8 is connected to the negative filtered analog voltage VOAF−. A biasing resistor R74 is connected between the base of BJT Q8 and the negative filtered analog supply voltage VOAF- to provide biasing current to the base of BJT Q8. Because the load 650 is capacitive in nature, it is important to provide a current path 614 to remove charge from the load 650 when a reduction in voltage of the output power signal VOUT is desired.

This current path 614 is provided by a diode D7 having its anode connected to the output power signal VOUT, which is also connected to the load 650, and the cathode of the diode D7 connected to the collector of the BJT Q8. Thus when the current through the BJT Q8 increases in response to a reduction in voltage of the amplifier input signal 612, it draws current away from the drive signal 618 and also, by virtue of the current path provided by the diode D7, pulls charge away from the load 650. The combination of the current path 614 and the use of a negative filtered analog supply voltage VOAF− enables a fast response time when the voltage of the output power signal VOUT needs to be reduced. As illustrated in the exemplary embodiment 600 of FIG. 6, a capacitor may be connected between the drive signal 618 and the emitter of the BJT Q12 to help stabilize the control signal 618.

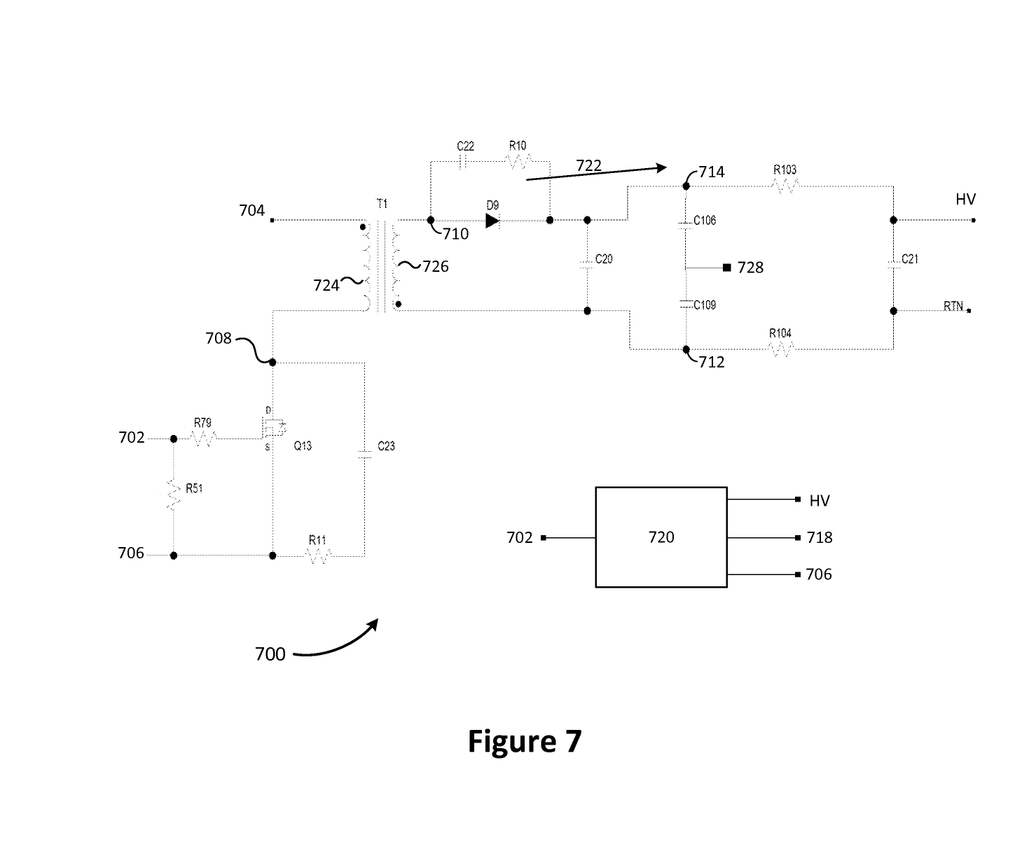

FIG. 7 illustrates a schematic diagram of an exemplary flyback type switching regulator appropriate for providing positive high voltage power HV derived from a low voltage supply power 704, such as the filtered positive analog supply voltage VOAF+ described above. Converter supply power, such as about positive twelve (12) volts, is applied to the converter to supply node 704. The converter power return is connected at node 706, also referred to as the converter return. A switching control signal is applied to node 702, also referred to as control signal 702, which is coupled to the gate G of the power switch Q13 through a pair of resistors R79 and R51 that are series connected between the gate of the power switch Q13 and the converter return 706. In the exemplary embodiment shown, the power switch Q13 is a field effect transistor (FET) with its source connected to the converter return 706. Alternatively any type of power switching device capable of rapidly and efficiently switching the necessary current and voltage may be used.

In the embodiment of FIG. 7, a series connected resistor R11 and capacitor C23 are connected across the drain and source of the power switch Q13 to condition the drain voltage 708 of the power switch Q13. When a voltage is applied to the control signal 702, the power switch Q13 conducts power between its source S and drain D, and the power switch Q13 is referred to as being ON, or in the ON state. When no voltage is applied to the control signal 702, the power switch Q13 has a high impedance between its source S and drain D, and the power switch Q13 is said to be OFF or in the OFF state.

The flyback converter 700 is formed by a transformer T1 acting as the input energy storage device, a diode D9 coupled between circuit nodes 710 and 714 in the forward current path 722, and output energy storage capacitors C20 and C21 coupled in parallel between the positive high voltage output power HV and the power return RTN. In operation the flyback converter 700 operates in two states, a first state where the power switch Q13 is turned ON, and a second state where the power switch Q13 is turned OFF.

During the first state, while the power switch Q13 is conducting, current flows through the transformer primary winding 724 to the converter power return 706 thereby transferring energy from the supply power 704 to the transformer T1. Energy stored in the output capacitors C20 and C21 continues to supply energy to the high voltage output HV while the transformer T1 is charging, and the diode D9 prevents the output capacitors from discharging through the transformer secondary winding 726.

During a second state, while the power switch Q13 is not conducting current, energy stored in the transformer T1 during the first state is transferred from the transformer secondary winding 726 to the output capacitors C20 and C21 through the diode D9. The transformer T1 has a turn ratio between the primary winding 724 and the secondary winding 726, such as about one to sixteen, causing the voltage at circuit node 710 to be greater than the supply voltage 704.

A controller 720 receives operating power from a low voltage analog supply voltage 718 such as the about positive 12 volt filtered analog supply voltage VOAF+ described above, and returns current to the converter power return 706. The controller 720 monitors the voltage of the output power HV and generates a control signal 702 that turns the power switch Q13 on and off as necessary to maintain the voltage of the output power HV at a substantially constant value, such as about positive one hundred and thirty volts (+130V). The high voltage power HV provided by the flyback converter 700 is appropriate as the high voltage power HV received by the high voltage amplifier 600.

Noise suppression and filtering is included in the exemplary flyback converter with the addition of passive components. Noise suppression is provided by a series connected resistor R10 and capacitor C22 coupled in parallel with the diode D9 to reduce high frequency voltage fluctuations across the diode D9. Two series connected capacitors C106 and C109 are connected in parallel across the first output capacitor C20 with their center node 728 connected to a chassis ground. The two output capacitors are stabilized with a resistor coupled between circuit node 714 and the high voltage output HV and a second resistor couple between circuit node 712 and the power return RTN.

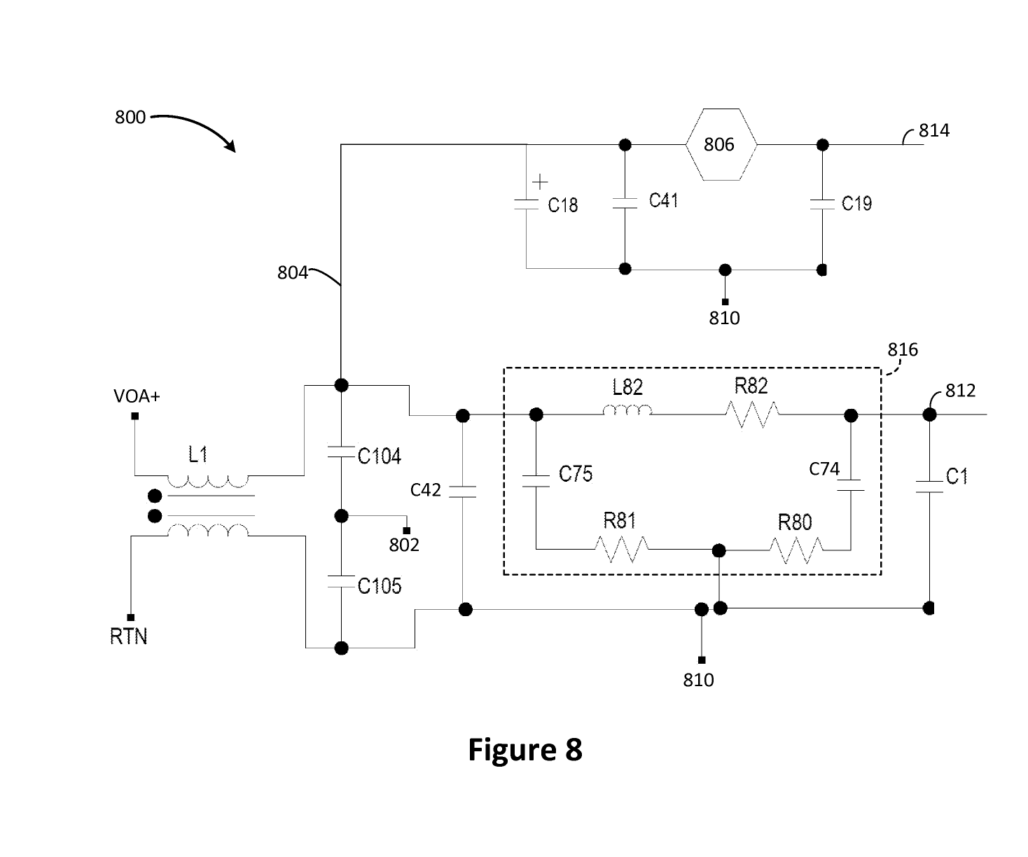

FIG. 8 illustrates a schematic diagram of an exemplary power conditioning circuit 800. Switching power converters, such as the exemplary flyback converter 700 can potentially generate significant amounts of electrical noise. The effects of electrical noise may be mitigated by conditioning supply power with a power conditioning or filtering circuit such as the exemplary power conditioning circuit 800.

A low voltage input power VOA+, such as the about positive twelve volt analog supply power described above, and the associated power return RTN are received across a common mode choke L1 and produces a first filtered power at node 804 and an associated converter power return at circuit node 810. The first filtered power is stabilized with a capacitor C42 connected across the first filtered power 804 and the converter return 810. Chassis stabilization is provided by a pair of series connected capacitors C104 and C105 coupled across the first filtered power 804 and converter return 810 with a center node 802 between the two capacitors C104 and C105 connected to a chassis ground (not shown).

The first filtered power 804 is appropriate for providing power to control circuitry such as the flyback converter controller 720. The first filtered power 804 may be further stabilized by a pair of capacitors C18 and C41 coupled in parallel across the first filtered power 804 and the converter return 810. A ferrite bead 806 may be placed between the first filtered power 804 and a second filtered power 814 to smooth current flow, with an additional capacitor C19 coupled across the second filtered power 814 and the converter return 810. The second filtered power 814 is appropriate for generation of a control signal for operating a flyback converter power switch such as the control signal 702 described above.

A low voltage supply power 812, such as the low voltage supply power 704 provided to the flyback converter 700 may be created form the first filtered power 804 with a filter network 816. The filter network 816 has a series connected capacitor C75 and resistor R81 coupled between the first filtered power 804 and the converter return 810 and a second series connected capacitor C74 and resistor R80 coupled between the low voltage supply power 812 and converter return with a series connected inductor L82 and resistor R82 coupled between the low voltage supply power 812 and the first filtered power 804.

The amplifying apparatus 100 as well as the exemplary circuit embodiments illustrated in FIGS. 2 through 8 may be advantageously employed in harsh environments where high levels of radiation are present. Equipment intended for use in high radiation environments such as space missions or high altitude flight often encounters high levels of ionizing radiation that can adversely affect electronic semiconductor devices. Ionizing radiation may be particle radiation or high-energy electromagnetic radiation and can have deleterious effects on electric components including lattice displacement, which can degrade semiconductor components such as bipolar junction transistors, and ionization effects that may be short term but may accumulate in semiconductor devices over time. To mitigate the effects of radiation, the amplifying apparatus, and particularly the semiconductor based components can be constructed to withstand or operate correctly when subjected to high doses of radiation. In certain embodiments the amplifying apparatus is radiation hardened, or made resistant to the damage caused by ionizing radiation. Such radiation hardened embodiments may be subjected to radiation up to and exceeding about 100,000 rads and continue to function correctly.

Thus, while there have been shown, described and pointed out, fundamental novel features of the invention as applied to the exemplary embodiments thereof, it will be understood that various omissions and substitutions and changes in the form and details of devices and methods illustrated, and in their operation, may be made by those skilled in the art without departing from the spirit and scope of the invention. Moreover, it is expressly intended that all combinations of those elements, which perform substantially the same function in substantially the same way to achieve the same result, are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. An amplifying apparatus comprising one or more amplifying channels, wherein each amplifying channel comprises:
a low pass filter configured to receive an analog signal and produce a filtered analog signal, wherein the low pass filter is configured to attenuate a frequency component of the analog signal having a frequency greater than a predetermined corner frequency; and
a linear amplifier coupled to the low pass filter and configured to receive the filtered analog signal and produce an output power signal wherein a voltage of the output power signal is a linear multiple of a voltage of the filtered analog signal.

2. The amplifying apparatus according to claim 1 wherein the linear amplifier comprises:
an input circuit configured to receive the filtered analog signal and produce a control signal;
an output transistor comprising a collector configured to receive a positive supply voltage, an emitter configured to produce the output power signal, and a base;
a second transistor comprising a collector coupled to the base of the output transistor, a collector configured to receive a negative supply voltage, and a base coupled to the control signal; and
a diode comprising an anode and a cathode, wherein the anode is coupled to the output power signal and the cathode is coupled to the collector of the second transistor.

3. The amplifying apparatus according to claim 2 wherein the output power signal comprises a voltage greater than one hundred volts, and the supply voltage comprises a voltage greater than one hundred volts.

4. The amplifying apparatus according to claim 2 wherein the low pass filter and the linear amplifier comprise radiation hardened components.

5. The amplifying apparatus according to claim 2 wherein the input circuit, the output transistor, the second transistor, and the diode are adapted to operate correctly when subjected to a total ionizing dose of radiation of less than or equal to one hundred thousand rad.

6. The amplifying apparatus according to claim 2 wherein each channel comprises a digital to analog converter coupled to the low pass filter, wherein the digital to analog converter is configured to receive a serial digital signal and to produce the analog signal wherein a voltage of the analog signal corresponds to a value of the serial digital signal.

7. The amplifying apparatus according to claim 6 wherein each amplifying channel comprises:
a differential receiver coupled to the digital to analog converter circuit, wherein the differential receiver is configured to receive a differential signal, and produce the serial digital signal, wherein the differential signal comprises serial digital data.

8. The amplifying apparatus according to claim 7 wherein the low pass filter comprises a Bessel filter, and wherein a full power bandwidth of the linear amplifier is greater than ten times the corner frequency.

9. An apparatus comprising an amplifying device coupled to a micro-electromechanical mirror, the amplifying device comprising four amplifying channels, and the micro-electromechanical mirror comprising a first axis of motion and a second axis of motion,
wherein a first amplifying channel and a second amplifying channel are coupled to the first axis and configured to differentially operate the first axis, and a third amplifying channel and a fourth amplifying channel are coupled to the second axis and are configured to differentially operate the second axis.

10. The apparatus of claim 9 wherein each of the four amplifying channels comprises:
a low pass filter configured to receive an analog signal and produce a filtered analog signal, wherein the low pass filter is configured to attenuate a frequency component of the analog signal having a frequency greater than a predetermined corner frequency; and
a linear amplifier coupled to the low pass filter and configured to receive the filtered analog signal and produce an output power signal wherein a voltage of the output power signal is a linear multiple of a voltage of the filtered analog signal.

11. The apparatus of claim 10 wherein the predetermined corner frequency is below a resonance of the micro-electromechanical mirror.

12. The amplifying apparatus according to claim 10 wherein the output power signal comprises a voltage greater than one hundred volts, and the supply voltage comprises a voltage greater than one hundred volts.

13. The amplifying apparatus according to claim 10 wherein the low pass filter and the linear amplifier comprise radiation hardened components.

14. The amplifying apparatus according to claim 10 wherein the input circuit, the output transistor, the second transistor, and the diode are adapted to operate correctly when subjected to a total ionizing dose of radiation of less than or equal to one hundred thousand rad.

15. The amplifying apparatus according to claim 10 wherein each of the four amplifying channels comprises a digital to analog converter coupled to the low pass filter, wherein the digital to analog converter is configured to receive a serial digital signal and to produce the analog signal wherein a voltage of the analog signal corresponds to a value of the serial digital signal.

16. The amplifying apparatus according to claim 15 wherein each of the four amplifying channels comprises:
a differential receiver coupled to the digital to analog converter circuit, wherein the differential receiver is configured to receive a differential signal, and produce the serial digital signal, wherein the differential signal comprises serial digital data.

17. The amplifying apparatus according to claim 16 wherein the low pass filter comprises a Bessel filter, and wherein a full power bandwidth of the linear amplifier is greater than ten times the corner frequency.
